(19) United States
(12) Patent Application Publication
(10) Pub. No.: US 2007/0068454 A1
(43) Pub. Date: Mar. 29, 2007

(54) Jig for manufacturing semiconductor devices and method for manufacturing the jig

(75) Inventor: Yoshihiro Saeki, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/524,319

(22) Filed: Sep. 21, 2006

(30) Foreign Application Priority Data
Sep. 27, 2005 (JP) 2005-279968

(51) Int. Cl. C23C 16/00

(52) U.S. Cl. 118/715; 118/724

(57) ABSTRACT

A jig is used for dicing a semiconductor device on which a plurality of chip regions are formed. The jig includes partitions that forms grids and a bottom wall the partitions are supported. When the semiconductor wafer is placed on the jig, the partitions support dicing regions of the semiconductor wafer such that at least one cavity is defined by the semiconductor wafer, the partitions, and the bottom wall. A negative pressure is created in the recesses by evacuating the air from the recesses. The semiconductor wafer is diced at the dicing regions into a plurality chips. The pressure in the recesses is returned to atmospheric pressure. Then, each of the chips is picked up from the jig.

### BACKGROUND OF THE INVENTION

1. Field of the Invention

The present invention relates to a jig for use in dicing a semiconductor wafer and a method for dicing a semiconductor wafer by the use of the jig.

2. Description of the Related Art

Conventionally, semiconductor wafers in which integrated circuits are fabricated into individual chips were diced in the following conventional process.

A dicing tape is a tape of resin having a predetermined thickness. An adhesive is applied to a surface of the dicing tape. The dicing tape is attached to the entire back surface of a semiconductor wafer.

The semiconductor wafer to which the dicing tape has been attached is placed face up on a dicing apparatus. Then, the semiconductor wafer is attracted to a chuck of the dicing apparatus by vacuum adsorption.

Then, a rotating blade is used to cut the semiconductor wafer along predetermined partition regions that surround individual chip areas. The blade cuts completely through the semiconductor wafer, reaching the surface of the dicing tape but not cutting completely through the dicing tape.

Then, a vacuum-equipped pickup head is positioned over the top surface of the chip. The pickup head is then lowered into contact with the semiconductor wafer, and the vacuum pressure of the pickup head attracts the chip. The arm is then controlled to lift the chip up and away from the dicing tape.

The aforementioned conventional method for dicing a semiconductor wafer suffers from the following problems. If bumps and wires are formed on the back surface of a semiconductor wafer for electrically connecting the chips to a wiring substrate, the bumps and wires may interfere with the dicing jig to create air gaps between the semiconductor wafer and the dicing tape. Especially, when the partition regions of the semiconductor wafer are not in intimate contact with the dicing tape, if the semiconductor wafer is moved relative to the dicing tape or is subjected to vibration during the dicing process, the semiconductor wafer may be cracked.

Conversely, forcibly making the semiconductor wafer in intimate contact with the dicing tape causes bumps, for example, to penetrate into the dicing tape, so that the semiconductor chips are difficult to detach from the dicing tape after dicing. Forcibly detaching the semiconductor chips may damage the chips. In other words, the requirements imposed on the dicing tape are opposing for dicing process and subsequent pickup process, and therefore are difficult to meet.

### SUMMARY OF THE INVENTION

An object of the present invention is to provide a jig for use with a semiconductor manufacturing apparatus, the jig allowing stable dicing and easy pickup of chips after dicing.

A jig is used for dicing a semiconductor device on which a plurality of chip regions are formed. The jig includes partitions that forms grids and a bottom wall the partitions are supported. When the semiconductor wafer is placed on the jig, the partitions support dicing regions of the semiconductor wafer such that at least one cavity is defined by the semiconductor wafer, the partitions, and the bottom wall.

The at least one cavity is one of a plurality of cavities, and each of the partitions is formed with a communication hole such that each of the plurality of cavities communicates with its adjacent one of the plurality of cavities. The jig further comprises an outer frame supported on the bottom wall and surrounding the partitions, the outer frame being formed with a hole through which the plurality of cavities communicate with the atmosphere.

The jig is formed of a light-transmitting material.

The bottom is formed of a light transmitting material.

The jig further includes a film placed on top surface of the partitions improving intimate contact of the semiconductor wafer with the top surfaces. When the semiconductor wafer is diced at the dicing regions, a dicing blade cuts completely through the semiconductor wafer and a part of the way through the film.

The bottom is formed of a material transparent to ultraviolet and the film is formed of a material that cures under irradiation of ultraviolet.

A method is used for manufacturing a semiconductor device on which a plurality of chip regions are surrounded by dicing regions. The method includes the steps of:
preparing a jig having a flat surface and recesses formed in the surface; and
placing a semiconductor wafer such that the dicing regions of the semiconductor wafer are supported on surface portions that define the recesses;
creating a negative pressure in the recesses by evacuating the air from the recesses;
dicing the semiconductor wafer at the dicing regions into a plurality chips;
returning the pressure in the recesses to atmospheric pressure; and
picking up each of the chips from the jig.

The returning is performed by making a hole in the jig, the hole being made on a side of the jig opposite a corresponding chip region of the semiconductor.

The jig is formed with communication holes through which the recesses communicate with one another, and one of the communication holes being in communication with the atmosphere;
wherein the creating is performed by evacuating the air from the recesses through the one of the communication holes; and
wherein the returning is performed by opening the one of the communication holes to the atmosphere.

The method further includes placing a resilient resin film between the flat surface of the jig and the semiconductor wafer.

The jig is made of a light-transmitting material, wherein the method further includes:
placing a UV-curing resin film between the flat surface of the jig and the semiconductor wafer, the placing the UV-curing resin film being performed before placing the semiconductor wafer; and
irradiating the jig with ultraviolet after returning the pressure in the recesses to atmospheric pressure.

The jig has a light-transmitting portion that defines bottoms of the recesses, the placing the semiconductor wafer is performed by monitoring the jig from outside of the bottom with a camera.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limiting the present invention, and wherein:

FIG. 1A is a top view illustrating a dicing jig of a first embodiment;

FIG. 1B is a cross sectional view taken along a line X-X of FIG. 1A;

FIG. 1C is an enlarged view of a portion depicted at Y in FIG. 1A;

FIGS. 2A-2D illustrate the method for dicing a semiconductor wafer using the dicing jig of the first embodiment;

FIG. 3 is a cross sectional view corresponding to FIG. 1B, illustrating the configuration of a dicing jig of a second embodiment;

FIG. 4 is a cross sectional view corresponding to FIG. 1B, illustrating the configuration of a dicing jig of a third embodiment;

FIG. 5A is a top view of a dicing jig of a fourth embodiment; and

FIG. 5B is a cross sectional view taken along a line Z-Z of FIG. 5A;

FIGS. 6A-6D illustrate the method for dicing a semiconductor wafer using the dicing jig of the fourth embodiment; and

FIG. 7 is a cross sectional view corresponding to FIG. 5B, illustrating the configuration of a dicing jig of a fifth embodiment.

### DETAILED DESCRIPTION OF THE INVENTION

A dicing jig according to the present invention includes a bottom and partitions that cross to form grids on the bottom. When a semiconductor wafer is placed on the dicing jig, the partitions support the semiconductor wafer at the dicing regions of the semiconductor wafer, so that cavities are defined between the semiconductor wafer, the partitions, and the bottom.

The semiconductor wafer may be placed on the dicing jig in a chamber and then the chamber is evacuated so that the pressure in the cavities is a negative pressure. Subsequently, the pressure in the chamber is brought back to atmospheric pressure, so that the semiconductor wafer remains attracted to the dicing jig by vacuum adsorption. The bumps and wires that project from the semiconductor wafer can project within the cavity, so that the bumps and wires are not obstacles to fixing the wafer to the dicing jig. Alternatively, the cavities may be evacuated through an outlet formed in the outermost frame of the dicing jig that surrounds the partitions, so that the semiconductor wafer is firmly attracted to the dicing jig by vacuum adsorption. In order to take individual chips out of the dicing jig after dicing, a hole may be made in the bottom of the dicing jig at each cavity or the outlet is opened to return the negative pressure in the cavities to atmospheric pressure. As described above, the dicing jig according to the present invention is advantageous in that the chips may be taken out from the dicing jig easily and promptly after dicing.

A film having a predetermined thickness is provided on the top surfaces of the partitions and outermost frame of the dicing jig, improving intimate contact of the semiconductor wafer with the dicing jig as well as protecting the partitions from being damaged during dicing. The dicing jig may be used repeatedly by replacing the film after dicing.

### FIRST EMBODIMENT

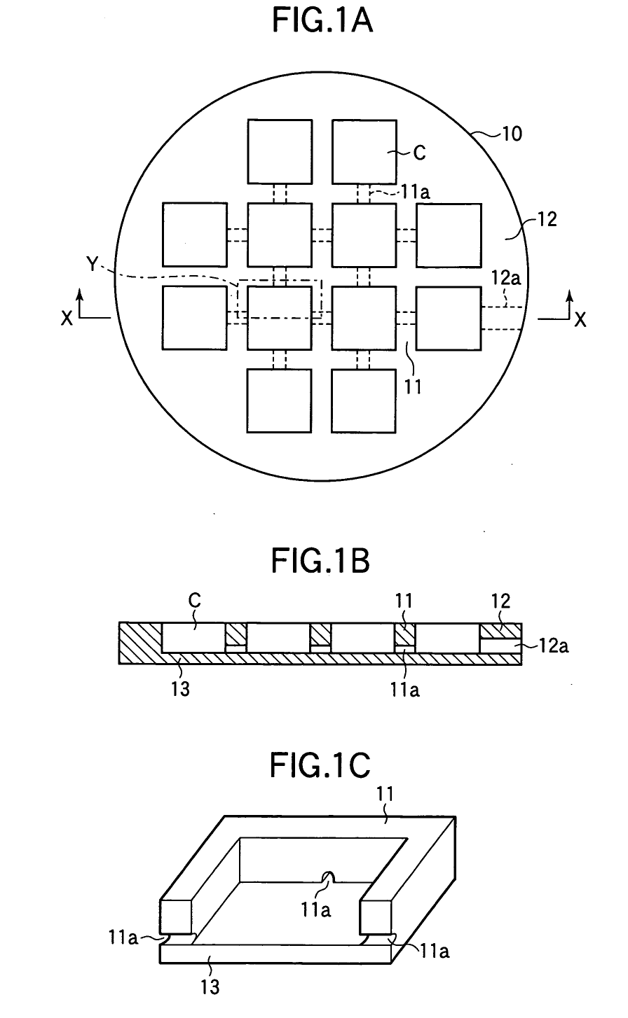

FIG. 1A is a top view illustrating a dicing jig 10 of the first embodiment. FIG. 1B is a cross sectional view taken along a line X-X of FIG. 1A. FIG. 1C is an enlarged view of a portion depicted at Y in FIG. 1A.

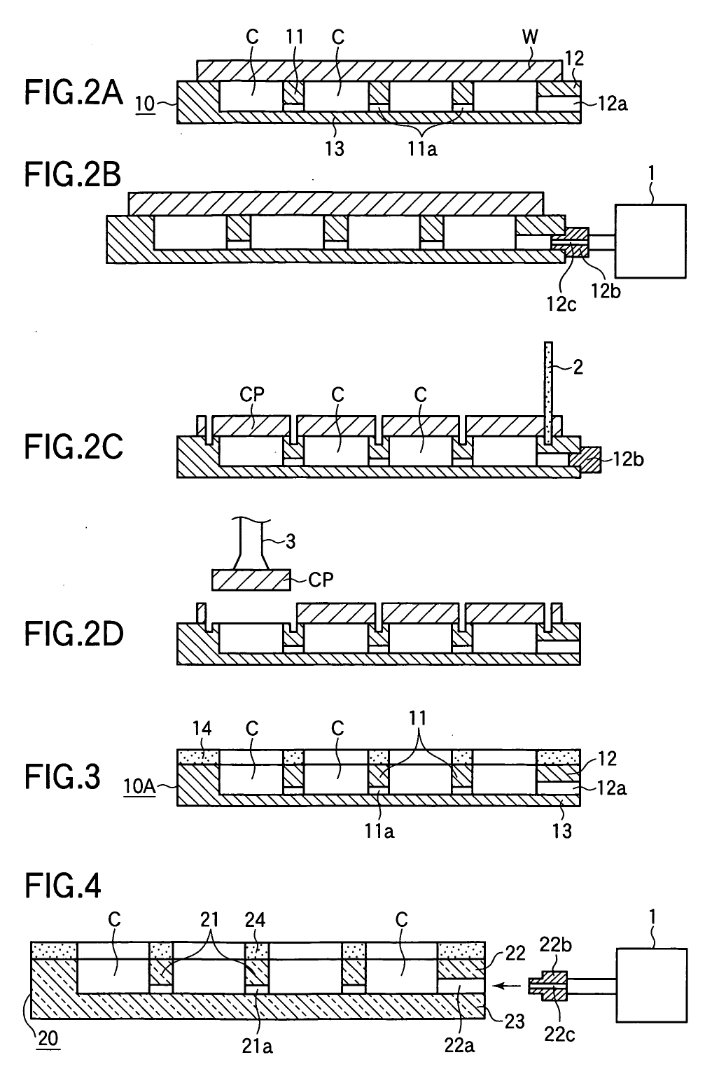

Referring to FIGS. 1A and 1B, the dicing jig 10 is of a one piece construction that includes partitions 11, an outer frame 12 formed to surround the partitions 11, a bottom 13 on which the partitions and the outer frame 12 are formed. The outer frame 12 has an outer diameter larger than that of a semiconductor wafer W (FIG. 2A).

The partitions 11 and outer frame 12 have the same height so that their top surfaces extend in the same plane. The partitions 11 define individual cavities C that are in communication with adjacent cavities via communication holes 11a formed in the partitions 11. An inlet/outlet 12a is formed in the outer frame 12 through which air in the individual cavities are evacuated or air is let in the cavities.

The dicing jig 10 is formed of a metal material such as aluminum or stainless steel. The overall diameter of the dicing jig 10 and the individual dimensions of the partitions 11 and outer frame 12 may be selected in accordance with the dimensions of the semiconductor wafer W. The depth of the cavities is selected to accommodate the height of bumps and wires formed on the back surface of the wafer. The thickness of the bottom 13 is determined by the required overall mechanical strength, and is usually about 0.5 mm.

FIGS. 2A-2D illustrate the method for dicing the semiconductor wafer W using the dicing jig 10 in FIGS. 1A-1C. The method of dicing the semiconductor wafer W by the use of the dicing jig 10 will be described.

Referring to FIG. 2A, the semiconductor wafer W is placed on the dicing jig 10 such that the bumps and wires formed on the back surface of the semiconductor wafer are accommodated in the cavities and the dicing regions of the semiconductor wafer W are aligned on the partitions 11.

Referring to FIG. 2B, a vacuum pump 1 is connected to the inlet/outlet 12a via a needle 12c inserted into a plug 12b, and evacuates theair from the cavities C through theneedle 12c. Thus, the pressure in the cavities C decreases so that the semiconductor wafer W is intimately attracted to the top surfaces of the partitions 11 and the outer frame 12 of the dicing jig 10. Subsequently, the needle 12c is removed from the plug 12b so that the plug 12b deforms to close the hole through which the needle 12c was extending, thereby maintaining the cavities C at a negative pressure.

The dicing jig 10 to which the semiconductor wafer W has been attracted is set onto a chuck of a dicing apparatus, not shown. Then, as shown in FIG. 2C, the semiconductor wafer W is diced along the dicing regions into individual chips CP by means of a rotating blade 2. The blade 2 is allowed to cut through the semiconductor wafer W to reach the surface of the partition 11 of the dicing jig 10.

As described above, the dicing jig 10 of the first embodiment includes partitions 11 that correspond to the dicing regions of the semiconductor wafer W, and the bottom 3 that cooperates with the partitions 11 to form the cavities C. The bumps and wires formed on the semiconductor wafer W project into the cavities C without interfering with any parts of the dicing jig 10 when the semiconductor wafer W is placed on the dicing jig 10. Evacuating the air from the cavities C enables the semiconductor wafer W to be intimately attached to the dicing jig 10, thereby providing reliable dicing and preventing the semiconductor wafer W from being cracked. Because the plug 12b is detached from the inlet/outlet 12a of the dicing jig 10 to bring the cavities C back to atmospheric pressure, the individual chips may be picked up from the dicing jig 10 without causing detachment of the chips from the dicing jig before they are picked up and damage to the chips when they are picked up.

### SECOND EMBODIMENT

FIG. 3 is a cross sectional view corresponding to FIG. 1B, illustrating the configuration of a dicing jig 10A of a second embodiment.

The dicing jig 10A differs from the dicing jig 10 in that a layer 14 is formed of a resilient resin material such as poly-silicone or silicone rubber and is placed on the top surfaces of partitions 11 and outer frame 12. The layer 14 has a thickness of about 0.1 mm. The layer 14 may be formed by applying a resin material to the surfaces or by attaching a pre-shaped thin resin film onto the top surfaces.

The dicing jig 10A can be used to dice a semiconductor wafer W in much the same way as the first embodiment. The semiconductor wafer W is placed on the dicing jig 10A such that the dicing regions of the semiconductor wafer W sit on the layer 14. A plug 12b having a needle 12c inserted therein is attached into an inlet/outlet 12a. Then, a vacuum pump 1 is connected to the inlet/outlet 12a to evacuate the air from the cavities C through the needle 12c. Then, the needle 12c is pulled out of the plug 12b, so that the plug 12b deforms to close the hole through which the needle 12c was extending. In this manner, the cavities are maintained at a negative pressure, thereby intimately fixing the wafer W on the dicing jig 10A by vacuum adsorption. Then, the dicing jig 10A having the semiconductor wafer W attracted to it is set onto a chuck of the dicing apparatus.

The semiconductor wafer W is diced along the dicing regions into individual chips by using a rotating blade 2. The blade 2 is allowed to cut completely through the semiconductor wafer W to just reach the surface of the layer 14, but is not allowed to reach the partitions 11 of the dicing jig 10A formed of a metal material.

Then, the plug 12b is detached from the inlet/outlet 12a allowing the pressure in the cavities C to return to atmospheric pressure. A pickup head 3 is used to pick up individual chips from the dicing jig 10A.

As described above, the layer 14 prevents the blade 2 from cutting into the metal part of the dicing jig 10A. In addition to the advantages of the first embodiment, the dicing jig 10A has the advantage that the layer 14 can be removed after use and a new layer may be laid on the jig 10A for reuse of the dicing jig 10A. The layer 14 of a resilient resin provides better adhesion than a metal surface, so that a good bonding force is still obtained even when the degree of vacuum of the cavities C is somewhat low. This is advantageous in that lower negative pressure in the cavities C exerts less mechanical stress on the semiconductor wafer W and therefore there should be less chance of the semiconductor wafer W being damaged.

### THIRD EMBODIMENT

FIG. 4 is a cross-sectional view corresponding to FIG. 1B, illustrating the configuration of a dicing jig 20 of a third embodiment.

The dicing jig 20 includes partitions 21, an outer frame 22, a bottom 23, and a layer 24 of UV curing resin formed on the top surfaces of the partitions 21 and the outer frame 22. Cavities C are defined between the partitions 21 and between the partitions 21 and the outer frame 22. The cavities C communicate with one another through communication holes 21a.

The dicing jig 20 differs from the dicing jig 10 in FIG. 1 in material. Thatis, the partitions 21, outer frame 22, and bottom 23 are in one piece construction of a UV transmitting material such as glass or plastics. The partitions 21, outer frame 22, and bottom 23 have substantially the same shapes as those in FIG. 1 except that the thickness of bottom 23 needs to be selected according to the mechanical strength of the material of the dicing jig 20.

The outer frame 12 has an outer diameter larger than that of a semiconductor wafer W. The layer 24 has a thickness of about 0.1 mm. The layer 24 may be formed by applying a resin material to the top surfaces of the partitions 21 and outer frame 22 or by attaching a pre-shaped thin film onto the top surfaces.

The dicing jig 20 can be used to dice the semiconductor wafer W in much the same way as the first embodiment. A semiconductor wafer W is placed on the dicing jig 20 such that the dicing regions of the semiconductor wafer W sit on the layer 24. Then, a vacuum pump 1 is connected to the inlet/outlet 22a via a needle 22o inserted into a plug 22b, and evacuates the air from the cavities C through the needle 22c. Thus, the pressure in the cavities C decreases so that the semiconductor wafer W is intimately attracted to the top surfaces of the partitions 11 and the outer frame 12 of the dicing jig 10. Subsequently, the needle 22c is removed from the plug 22b so that the plug 22b deforms to close the hole through which the needle 22c was extending, thereby maintaining the cavities C at a negative pressure. Then, the dicing jig 20 having the semiconductor wafer W on it is set onto a chuck of a dicing apparatus.

The semiconductor wafer W is diced along the dicing regions into individual chips by using a rotating blade 2. The blade 2 is allowed to cut completely through the semiconductor wafer W to just reach the surface of the layer 24, but is not allowed to reach the partitions 11 of the dicing jig 20.

Then, the dicing jig 20 is irradiated from the back surface of the bottom 23 with ultraviolet light so that the layer 24 is UV-cured to reduce adhesion of the layer 24 to the semiconductor wafer W. Subsequently, the plug 22b is detached from the inlet/outlet 22a, thereby bringing the pressure in the cavities C to atmospheric pressure. A vacuum-equipped pickup head 3 is used to pick up individual chips from the dicing jig 20.

In addition to the advantages of the first embodiment, the dicing jig 10A has the advantage that the layer 24 can be removed after use and a new layer may be laid on the jig 10A for reuse of the jig. The layer 24 formed of a resilient resin provides better adhesion than a metal surface, so that a good bonding force is still obtained even when the degree of vacuum of the cavities is somewhat low. This is advantageous in that lower negative pressure in the cavities C exerts less mechanical stress on the semiconductor wafer W and therefore there should be less chance of the semiconductor wafer W being damaged. The use of the layer 24 of a UV curing resin offers improved adhesion of the semiconductor wafer W to the dicing jig 20, allowing a stable dicing process. Irradiating the layer 24 with ultra-violet shortly before the chips are picked up from the dicing jig 20 decreases the adhesion of the semiconductor wafer W to the dicing jig 20, facilitating the pickup operation of the chips by means of the pickup head 3.

### FOURTH EMBODIMENT

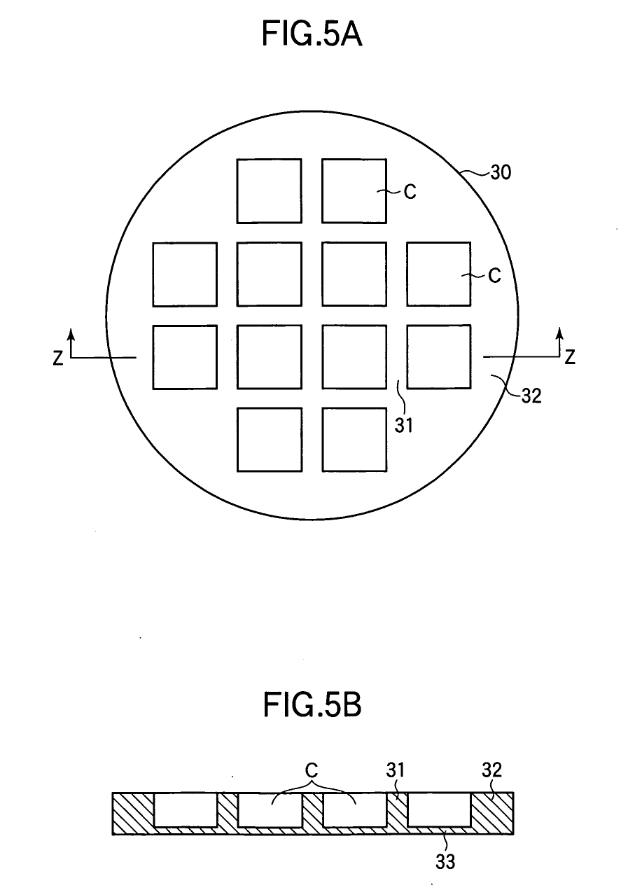

FIG. 5Ais a top viewofa dicingjig 30 of a fourth embodiment. FIG. 5B is a cross-sectional view taken along a line Z-Z of FIG. 5A.

The dicing jig 30 is formed of a resin material such as plastics, and includes partitions 31, an outer frame 32 formed to surround the partitions 31, a bottom 33 on which the partitions 31 and the outer frame 32 are formed. The outer frame 32 has a larger outer diameter larger than a semiconductor wafer W.

The partitions 31 and outer frame 32 are the same height so that their top surfaces are flush with one another other. In other words, the top surfaces are in the same plane. The partitions 31, outer frame 32, and bottom 33 define individual cavities C that are independent of one another. In other words, the dicing jig 30 has neither communication holes formed across adjacent cavies nor inlet/outlet as opposed to the first to third embodiments.

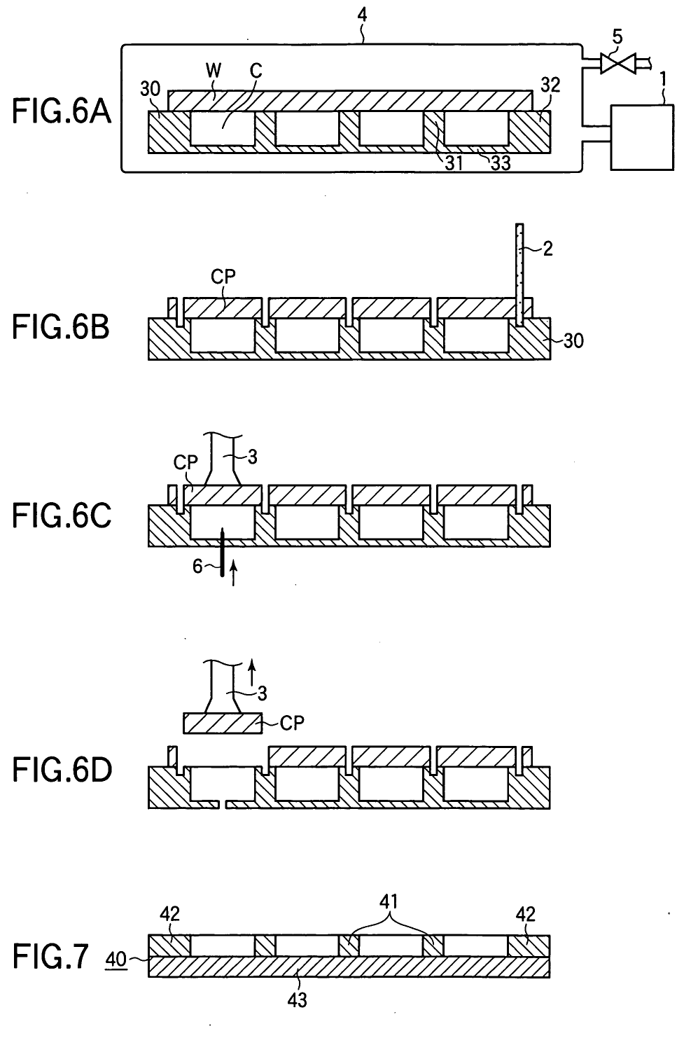

FIG. 6A illustrates the method for dicing the semiconductor wafer using the dicing jig 30 of the fourth embodiment. The method will be described with reference to FIG. 5.

Referring to FIG. 6A, the semiconductor wafer W is placed on the dicing jig 30 so that the dicing regions of the wafer sit on the partitions 31 with bumps and wires formed on the wafer not interfering with the partitions 31. Then, the dicing jig 30 on which the semiconductor wafer W sits is placed in a gastight chamber 4. A vacuum pump 1 evacuates the air from the chamber 4 through a valve 5 so that the individual cavities C are at a negative pressure.

Thus, the negative pressure in the respective cavities C effectively attracts the semiconductor wafer W such that the semiconductor wafer W is in intimate contact with the partitions 31 and outer frame 32. Then, the valve 5 is opened to bring the pressure in the cavities to atmospheric pressure.

The dicing jig 30 to which the semiconductor wafer W has been attracted is set onto a chuck of a dicing apparatus, not shown. Then, as shown in FIG. 6B, the semiconductor wafer W is diced along the dicing regions into individual chips CP by means of a rotating blade 2. The blade 2 is allowed to cut completely through the semiconductor wafer into the surface of the partition 31 of the dicing jig 30.

Then, as shown in FIG. 6C, the dicing jig 30 to which a plurality of chips CP have been attracted is set onto a dice pickup apparatus, not shown. After a pickup head 3 is positioned on the chip CP, a pin 6 is forced into the bottom 33 thereby allowing the pressure in the cavity C to return to atmospheric pressure.

Then, as shown in FIG. 6D, the pickup head 3 picks up the chip CP from the dicing jig 30.

Because the dicing jig 30 of the third embodiment has no communication holes and inlet/outlet as opposed to the first to third embodiments, the dicing jig 30 is simple in construction and easy to manufacture.

Just as in the first embodiment, when the semiconductor wafer W is positioned on the dicing jig 30, the bumps and wires formed on the semiconductor wafer W are comfortably accommodated in the cavities defined by the partitions 31 and bottom 33. Thus, there is no possibility of the bumps and wires on the semiconductor wafer W being damaged. The negative pressure in the cavities C effectively attracts the semiconductor wafer W such that the dicing regions of the wafer are in intimate contact with the partitions 31, ensuring reliable dicing and preventing the chips CP from being cracked. Because the negative pressure in the cavity C is brought back to atmospheric pressure by the forcible entry of the pin through the bottom into the cavity C, the chip CP can be picked up from the dicing jig without being detached forcibly.

Unlike the first to third embodiments, the cavities C are brought back to atmospheric pressure on a cavity-to-cavity basis so that the chips CP remaining on the dicing jig remain positioned accurately.

### FIFTH EMBODIMENT

FIG. 7 is a cross sectional view corresponding to FIG. 5B, illustrating the configuration of a dicing jig 40 of a fifth embodiment.

The dicing jig 40 includes partitions 41, an outer frame 42, a dicing tape 43 attached to the bottoms of the partitions 41 and outer frame 42. The partitions 41 and outer frame 42 are formed of a metal material such as aluminum, and are in one piece construction. The outer frame 12 has a larger outer diameter than a semiconductor wafer W. The dicing tape 43 is transparent to visible light or infrared.

The dicing jig 40 can be used to dice the semiconductor wafer W in much the same way as the fourth embodiment. A semiconductor wafer W is placed on the dicing jig 40 such that the dicing regions of the semiconductor wafer W sit on the partitions 41. Then, a vacuum pump 1 is connected to an inlet/outlet 22a to evacuate the air from the cavities C, thereby fixing the wafer W on the dicing jig 40. The positioning of the semiconductor wafer W with respect to the dicing jig 40 is performed by monitoring the back surface of the dicing jig 40 from under the dicing jig 40 with a visible light-based camera or an infrared-based camera.

Then, a valve 5 of a gastight enclosure 4 is opened to return the pressure in the gastight enclosure 4 to atmospheric pressure. The pressure in the cavities C is now a negative pressure such that the semiconductor wafer W is firmly attracted to the dicing jig 40.

The dicing jig 40 to which the semiconductor wafer W remains attracted is set onto a chuck of the dicing apparatus. Then, a rotating blade 2 is used to cut the semiconductor wafer W along predetermined partition regions into individual chips. The blade 2 cuts completely through the semiconductor wafer W into the partitions 41.

Then, the dicing jig 40 to which a plurality of individual chips have been attracted is set onto a dice pickup apparatus, not shown. After a pickup head 3 is positioned on a chip, a pin 6 is forced into the bottom 33, thereby allowing the pressure in the cavity C to return to atmospheric pressure. Then, the pickup head 3 picks up the chip from the dicing jig 40.

As described above, because the bottom 43 of the dicing jig 40 is formed of a light-transmitting dicing tape, the dicing jig 40 has the advantage, in addition to those of the fourth embodiment, that the semiconductor wafer W is accurately positioned with F05ED0077 respect to the dicing jig 40.

The fifth embodiment is more advantageous than the first to fourth embodiments in that the semiconductor wafer W can be positioned with small positional errors, thereby implementing small dimensions of the cavities C and dimensions between the cavities C.

The fifth embodiment enables accurate positioning of the semiconductor wafer W relative to the dicing jig 40 without precision robot arms or a special camera, eliminating the need for expensive manufacturing facilities.

Modifications

Various modifications may be made without departing from the scope of the invention.
(1) The dicing jigs according to the present invention may be applied not only to semiconductor wafers having bumps and wires but also those having a flat surface.
(2) Dicing may be performed not only with a rotating blade but also using a laser beam.
(3) For the dicing jig 20 of the third embodiment formed of, for example, glass, the semiconductor wafer W may be positioned with respect to the dicing jig 20 by observing the dicing jig from the bottom just as in the fifth embodiment, in which case the semiconductor wafer W may be positioned with small positional errors and therefore the chips may be smaller.
(4) A resilient resin material similar to that of the second embodiment may be applied to the top surfaces of the partitions 31 and outer frame 32 of the dicing jig 30 of the fourth embodiment, thereby increasing the adhesion of the semiconductor wafer W to the dicing jig just as in the second embodiment.
(5) The dicing jig 30 of the fourth embodiment may be made of a material transparent to ultraviolet similar to that of the third embodiment, and a UV curing resin similar to that of the third embodiment may be applied to the top surfaces of the partitions 31 and outer frame 32, thereby increasing the adhesion of the semiconductor wafer W to the dicing jig just as in the third embodiment.
(6) A resilient resin material similar to that of the second embodiment or a UV curing resin similar to that of the third embodiment may be applied to the top surfaces of the partitions 41 of the dicing jig 40 of the fifth embodiment, thereby improving the adhesion of the semiconductor wafer W to the dicing jig and allowing reuse of the partitions 41 just as in the second and third embodiments.
(7) While the dicing jig 40 of the fifth embodiment uses partitions 41 of a metal material, the partitions 41 are not limited to a metal. For example, the partitions 41 may be in the form of a film of polyimide. A polyimide film may be applied to the top surfaces of the dicing tape 42, then the dicing jig is patterned by photolithography, and is finally etched to form a film having partitions and an outer frame.

The invention being thus described, it will be obvious that the same may be varied in many ways. Such variations are not to be regarded as a departure from the spirit and scope of the invention, and all such modifications as would be obvious to one skilled in the art intended to be included within the scope of the following claims.

What is claimed is:

1. A jig for dicing a semiconductor device on which a plurality of chip regions are formed, the jig comprising:
partitions arranged to form grids; and
a bottom wall on which said partitions are supported;
wherein when the semiconductor wafer is placed on the jig, said partitions support dicing regions of the semiconductor wafer such that at least one cavity is defined by the semiconductor wafer, said partitions, and said bottom wall.

2. The jig according to claim 1, wherein the at least one cavity is one of a plurality of cavities, and each of the partitions is formed with a communication hole such that each of the plurality of cavities communicates with its adjacent one of the plurality of cavities,
wherein the jig further comprises an outer frame supported on said bottom wall and surrounding said partitions, said outer frame being formed with a hole through which the plurality of cavities communicate with the atmosphere.

3. The jig according to claim 1, wherein the jig is formed of a light-transmitting material.

4. The jig according to claim 1, wherein said bottom is formed of a light transmitting material.

5. The jig according to claim 1 further comprising a film placed on top surface of said partitions improving intimate contact of the semiconductor wafer with the top surfaces;
wherein when the semiconductor wafer is diced at the dicing regions, a dicing blade cuts completely through the semiconductor wafer and a part of the way through the film.

6. The jig according to claim 1, wherein said bottom is formed of a material transparent to ultraviolet and the film is formed of a material that cures under irradiation of ultraviolet.

7. A method of manufacturing a semiconductor device on which a plurality of chip regions are surrounded by dicing regions, comprising the steps of:
preparing a jig having a flat surface and recesses formed in the surface; and
placing a semiconductor wafer such that the dicing regions of the semiconductor wafer are supported on surface portions that define the recesses;
creating a negative pressure in the recesses by evacuating the air from the recesses;
dicing the semiconductor wafer at the dicing regions into a plurality chips;
returning the pressure in the recesses to atmospheric pressure; and
picking up each of the chips from the jig.

8. The method according to claim 7, wherein said returning is performed by making a hole in the jig, the hole being made on a side of the jig opposite a corresponding chip region of the semiconductor.

9. The method according to claim 7, wherein the jig is formed with communication holes through which the recesses communicate with one another, and one of the communication holes being in communication with the atmosphere;
wherein said creating is performed by evacuating the air from the recesses through the one of the communication holes; and
wherein said returning is performed by opening the one of the communication holes to the atmosphere.

10. The method according to claim 7, wherein further including placing a resilient resin film between the flat surface of the jig and the semiconductor wafer.

11. The method according to claim 7, wherein the jig is made of a light-transmitting material, wherein the method further includes:
placing a UV-curing resin film between the flat surface of the jig and the semiconductor wafer, said placing the UV-curing resin film being performed before placing the semiconductor wafer; and
irradiating the jig with ultraviolet after returning the pressure in the recesses to atmospheric pressure.

12. The method according to claim 7, wherein the jig has a light-transmitting portion that defines bottoms of the recesses, said placing the semiconductor wafer is performed by monitoring the jig from outside of the bottom with a camera.
